(19) United States
(12) Patent Application Publication
(10) Pub. No.: US 2009/0194862 A1
(43) Pub. Date: Aug. 6, 2009

(54) SEMICONDUCTOR MODULE AND METHOD OF MANUFACTURING THE SAME

(75) Inventor: Akio Kitami, Aichi-ken (JP)

Correspondence Address: SUGHRUE MION, PLLC, 2100 PENNSYLVANIA AVENUE, N.W., SUITE 800, WASHINGTON, DC, 20037, US

(73) Assignee: Toyota Jidosha Kabushiki Kaisha, Toyota-shi, Aichi-ken (JP)

(21) Appl. No.: 12/304,896

(22) PCT Filed: Jun. 8, 2007
(86) PCT No.: PCT/JP2007/062070

§ 371 Date: Dec. 15, 2008

(30) Foreign Application Priority Data
Jun. 15, 2006 (JP) 2006-166222

(51) Int. Cl. H01L 23/488; H01L 21/56; H01L 23/367

(52) U.S. Cl. 257/690; 438/122; 257/706; 257/E21.502; 257/E23.023; 257/E23.103

(57) ABSTRACT

There is provided a semiconductor module having improved heat radiation efficiency. A semiconductor module includes a semiconductor element, a pair of Cu heat radiating plates sandwiching the semiconductor element, insulating and heat radiating plates sandwiching the Cu heat radiating plates, heat radiating fins sandwiching the insulating and heat radiating plates, and solder applied between the Cu heat radiating plates and the insulating and heat radiating plates as well as between the insulating and heat radiating plates and the heat radiating fins.

### TECHNICAL FIELD

The present invention relates to a semiconductor module, and in particular, to a double-sided cooling type semiconductor module in which both surfaces of a semiconductor element are cooled.

### BACKGROUND ART

Semiconductor modules are conventionally disclosed in, for example, Japanese Patent Laying-Open No. 2001-352023, Japanese Patent Laying-Open No. 10-223810, Japanese Patent Laying-Open No. 2004-221547, Japanese Patent Laying-Open No. 2005-259748, and Japanese Patent Laying-Open No. 2004-235175.

### DISCLOSURE OF THE INVENTION

Japanese Patent Laying-Open No. 2001-352023 discloses an art in which a semiconductor module is sandwiched by a flat and zigzag refrigerant tube, so that both surfaces of one or the required number of double-sided heat radiating semiconductor modules are equally and satisfactorily cooled with a single refrigerant tube.

Japanese Patent Laying-Open No. 10-223810 discloses an art in which an insulating substrate is connected to a power semiconductor element and a heat radiating plate by solder on the upper and lower surfaces, respectively.

Japanese Patent Laying-Open No. 2004-221547 discloses a substrate including an insulating substrate, a circuit layer laminated on one side of the insulating substrate, a metal layer laminated on the other side of the insulating substrate, a semiconductor chip mounted on the circuit layer with solder interposed therebetween, and a radiator joined to the metal layer.

Japanese Patent Laying-Open No. 2005-259748 discloses first and second power semiconductor modules having power semiconductor elements mounted thereon and having metallic bases on the bottom surfaces thereof The first and second power semiconductor modules are mounted on both surfaces of a cooling medium flow path.

Japanese Patent Laying-Open No. 2004-23 5175 discloses a power semiconductor module in which a linear fin is provided in a region under an insulating substrate on the opposite surface of a metallic base surface to which the insulating substrate is bonded, and the insulating substrate is shaped such that the length of the linear fin in the stripe direction is not greater than that in the vertical direction.

In the conventional arts, for example in Japanese Patent Laying-Open No. 2001-352023, however, thermal resistance between a metallic plate and a cooling plate is high and cooling performance is low.

Therefore, the present invention is directed to solving the above-described problems, and an object thereof is to provide a semiconductor module having high cooling performance.

A semiconductor module according to the present invention includes a semiconductor element, a metallic plate sandwiching the semiconductor element, an insulating plate sandwiching the metallic plate, a cooling device sandwiching the insulating plate, and solder applied between the metallic plate and the insulating plate as well as between the insulating plate and the cooling device, respectively.

In the semiconductor module configured in such a manner, the solder is applied between the metallic plate and the insulating plate as well as between the insulating plate and the metallic plate, respectively, so that heat transfer through the solder is increased. As a result, cooling efficiency can be improved.

It should be noted that “solder” herein refers to a metallic material having a melting point lower than those of the metallic plate, the insulating plate and the cooling device, and a material melted to be interposed therebetween and solidified to connect these. Therefore, the solder is not limited to an alloy of tin and lead, but may be solder that does not contain lead, that is, lead-free solder.

Preferably, the cooling device is a heat radiating fin.

Preferably, the semiconductor module further includes a resin molding the semiconductor element.

Preferably, the semiconductor module further includes solder interposed between the metallic plate and the semiconductor element, and transmitting heat of the semiconductor element to the metallic plate.

It should be noted that at least two configurations out of the above-described configurations may be appropriately combined.

A method of manufacturing a semiconductor module according to the present invention includes the steps of: sandwiching a semiconductor element by a pair of metallic plates; sandwiching the metallic plates by a pair of insulating plates; and sandwiching the insulating plates by a pair of cooling devices, the step of sandwiching the metallic plates by a pair of insulating plates including the step of interposing solder between the insulating plates and the metallic plates, and the step of sandwiching the insulating plates by a pair of cooling devices including the step of interposing solder between the cooling devices and the insulating plates.

The present invention may be configured by combining more than one of the above-described configurations.

According to the present invention, there can be provided a semiconductor module having improved cooling efficiency.

### BRIEF DESCRIPTION OF THE DRAWINGS

FIG. 1 is a cross-sectional view of a semiconductor module according to an embodiment of the present invention.

### BEST MODES FOR CARRYING OUT THE INVENTION

The embodiments of the present invention will be described hereinafter with reference to the drawings. It should be noted that the same or corresponding parts are represented by the same reference characters in the following embodiments, and the description thereof will not be repeated.

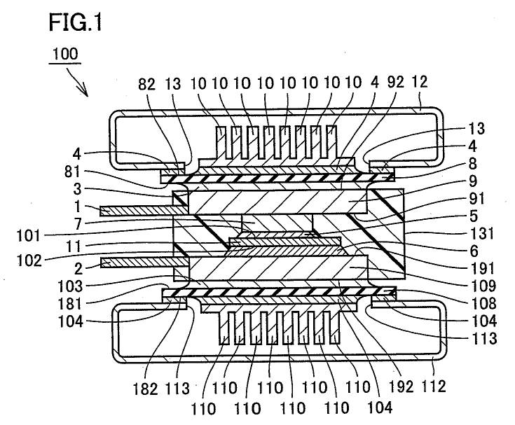

FIG. 1 is a cross-sectional view of a semiconductor module according to an embodiment of the present invention. Referring to FIG. 1, a semiconductor module 100 according to the embodiment of the present invention has a semiconductor element 11. Semiconductor element 11 has a first main surface 101 and a second main surface 102. First main surface 101 and second main surface 102 contact solder 5 and 6. Solder 5 and 6 constitute a part of a circuit for sending an electrical signal to semiconductor element 11. Solder 5 and 6 also function as a thermal path through which heat generated from semiconductor element 11 is released outside.

Semiconductor element 11 is an element forming an inverter, a converter or the like, and processes an electrical signal. Current flows through semiconductor element 11 and causes semiconductor element 11 to generate heat.

A heat block 7 made up of a metallic block contacts solder 5. Heat block 7 acts as a heat sink.

Heat block 7 contacts a Cu heat radiating plate 9. Cu heat radiating plate 9 is made from copper and serves as a heat sink and a heat spreader. In other words, since copper has good thermal conductivity, heat transmitted from heat block 7 spreads across Cu heat radiating plate 9 and heat radiation capability is improved. A lead 1 is connected to Cu heat radiating plate 9. Lead 1 is a metallic terminal for input/output of electrical signals, and an electrical signal input from lead 1 is sent through Cu heat radiating plate 9, heat block 7 and solder 5 to semiconductor element 11.

Solder 6 contacts a Cu heat radiating plate 109. Lead 2 is connected to Cu heat radiating plate 109, and electrical signals are input/output from lead 2. An electrical signal sent from lead 2 is transmitted through Cu heat radiating plate 9 and solder 6 to semiconductor element 11.

Cu heat radiating plates 9 and 109, heat block 7, solder 5 and 6, and semiconductor element 11 are covered with a mold resin 131. Mold resin 131 covers semiconductor element 11, so that the application of stress to semiconductor element 11 from outside is prevented. Mold resin 131 also serves as a protection member preventing a chemical reaction or the like of semiconductor element 11.

Cu heat radiating plates 9 and 109 have first main surfaces 91 and 191 located inside, and second main surfaces 92 and 192 located outside.

Solder 3 contacts second main surface 92 of Cu heat radiating plate 9. Solder 3 is connected to an insulating and heat radiating plate 8. Insulating and heat radiating plate 8 contacts a heat radiating fin 10 and a cooler 12 by solder 4. Heat radiating fin 10 is fit in an opening 13 of cooler 12. A first main surface 81 of insulating and heat radiating plate 8 is connected to solder 3, and a second main surface 82 is connected to solder 4.

Heat radiating fin 10 is shaped such that a plurality of blade members extending in the thickness direction are formed on a flat plate, and the surface area thereof is increased, so that heat radiation efficiency is improved. Cooler 12 is shaped so as to surround and protect heat radiating fin 10. It should be noted that cooling efficiency by heat radiating fin 10 may further be enhanced by causing air or the like to forcibly flow through cooler 12.

Solder 103 contacts second main surface 192 of Cu heat radiating plate 109. Solder 103 is connected to an insulating and heat radiating plate 108. Insulating and heat radiating plate 108 contacts a heat radiating fin 110 and a cooler 112 by solder 104. Heat radiating fin 110 is fit in an opening 113 of cooler 112. A first main surface 181 of insulating and heat radiating plate 108 is connected to solder 103, and a second main surface 182 is connected to solder 104.

Heat radiating fin 10 is shaped such that a plurality of blade members extending in the thickness direction are formed on a flat plate, and the surface area thereof is increased, so that heat radiation efficiency is improved. Cooler 12 is shaped so as to surround and protect heat radiating fin 10. It should be noted that cooling efficiency by heat radiating fin 10 may further be enhanced by causing air or the like to forcibly flow through cooler 12.

In other words, double-sided cooling type semiconductor module 100 according to the present invention includes semiconductor element 11, Cu heat radiating plates 9 and 109 serving as a pair of metallic plates sandwiching semiconductor element 11, insulating and heat radiating plates 8 and 108 serving as insulating plates sandwiching Cu heat radiating plates 9 and 109, heat radiating fins 10 and 110 serving as cooling devices sandwiching insulating and heat radiating plates 8 and 108, and solder 3, 4, 103, and 104 applied between Cu heat radiating plates 9 and 109 and insulating and heat radiating plates 8 and 108 as well as between insulating and heat radiating plates 8 and 108 and heat radiating fin 10.

Semiconductor module 100 further includes mold resin 131 molding semiconductor element 11. Semiconductor module 100 further includes solder 5 and 6 interposed between Cu heat radiating plates 9 and 109 and semiconductor element 11, and transmitting heat of semiconductor element 11 to Cu heat radiating plates 9 and 109.

Cu heat radiating plates 9 and 109 are not necessarily be made from copper and have only to ensure at least electrical conduction. More preferably, Cu heat radiating plates 9 and 109 are made from a material having excellent thermal conductivity. For example, aluminum or the like can be used other than copper.

Preferably, insulating and heat radiating plates 8 and 108 are electrical insulators and have high heat transfer coefficient.

In the present invention, heat radiating fins 10 and 110 are attached by soldering to double-sided molded Cu heat radiating plates 9 and 109. Openings 13 and 113 are created in coolers 12 and 112, and heat radiating fins 10 and 110 are soldered to double-sided molded Cu heat radiating plates 9 and 109, so that a sealing property is ensured.

In the semiconductor module configured in such a manner, the solder is used at the connecting portions, so that the amount of heat transfer through the solder is increased and cooling efficiency can be enhanced.

In other words, a structure having insulating and heat radiating plates 8 and 108 as well as heat radiating fins 10 and 110 serving as cooling fins, by soldering, on Cu surfaces of a double-sided molded power card is employed. As a result, a double-sided molded structure having no heat radiation grease can be achieved.

It should be understood that the embodiments disclosed herein are illustrative and not limitative in any respect. The scope of the present invention is defined by the terms of the claims, rather than the description above, and is intended to include any modifications within the scope and meaning equivalent to the terms of the claims.

1. A semiconductor module, comprising:
a semiconductor element;
metallic plates sandwiching said semiconductor element;
insulating plates sandwiching said metallic plates;
cooling devices sandwiching said insulating plates; and
solder applied between said metallic plates and said insulating plates as well as between said insulating plates and said cooling devices, respectively,
said cooling devices being each a heat radiating fin,
the semiconductor module further comprising
a cooler shaped so as to surround and protect said heat radiating fin.

2. The semiconductor module according to claim 1, wherein
said cooling devices are each a heat radiating fin.

3. The semiconductor module according to claim 1, further comprising
a resin molding said semiconductor element.

4. The semiconductor module according to claim 1, further comprising
solder interposed between said metallic plates and said semiconductor element, and transmitting heat of said semiconductor element to said metallic plates.

5. A method of manufacturing a semiconductor module, comprising the steps of:
sandwiching a semiconductor element by a pair of metallic plates;
sandwiching said metallic plates by a pair of insulating plates; and
sandwiching said insulating plates by a pair of cooling devices,
said step of sandwiching said metallic plates by a pair of insulating plates including the step of interposing solder between said insulating plates and said metallic plates, and
said step of sandwiching said insulating plates by a pair of cooling devices including the step of interposing solder between said cooling devices and said insulating plates.

6. The semiconductor module according to claim 1, further comprising:
a lead connected to said metallic plates;
a heat block interposed between said semiconductor element and said metallic plates, and made from copper;
a resin molding said semiconductor element; and
another solder interposed between said metallic plates and said semiconductor element, and transmitting heat of said semiconductor element to said metallic plates,
said cooling devices being each said heat radiating fin,
the semiconductor module further comprising
a cooler shaped so as to surround and protect said heat radiating fin.
